(19) United States
(12) Patent Application Publication
(10) Pub. No.: US 2007/0103067 A1
(43) Pub. Date: May 10, 2007

(54) Organic electroluminescence device and electron transporting layer

(76) Inventors: Ya-Ping Tsai, Nantou City (TW); Chih-Hsien Chi, Cingshuei Township (TW); Shuenn-Jiun Tang, Jhubei City (TW); Jie-Huang Wu, Pingjhen City (TW)

Correspondence Address: J.C. Patents, Inc., Suite 250, 4 Venture, Irvine, CA, 92618, US

(21) Appl. No.: 11/269,972

(22) Filed: Nov. 8, 2005

(51) Int. Cl. H01L 51/54

(52) U.S. Cl. 313/506; 428/690; 428/917; 428/212; 313/504

(57) ABSTRACT

An organic electroluminescence device comprises a substrate, a first electrode layer, a hole transportation layer, a luminescence layer, an electron transportation layer and a second electrode layer. In addition, on the substrate is disposed the first electrode layer on which the hole transportation layer is further disposed. In addition, on the hole transportation layer is disposed the luminescence layer on which the electron transportation layer is further disposed, and eventually the second electrode layer is disposed on the electron transportation layer. Moreover, the electron transportation layer comprises n+1 first sub-transportation layers and n second sub-transportation layers, wherein n is an integer. The n+1 first sub-transportation layers are stacked on the luminescence layer, each of the n second sub-transportation layers is disposed between every two neighbor first sub-transportation layers and a band-gap of the first sub-transportation layer is different from that of second sub-transportation layer.

### BACKGROUND OF THE INVENTION

1. Field of the Invention

The present invention generally relates to a luminescence device, and more particularly to, an organic electroluminescence device and an electron transportation layer thereof.

2. Description of Related Art

Displays are communication interfaces between human and information processors, and have current trends in planar displays. Among displays, an organic electroluminescence display (OLED) is believed to be a main stream of the next generation planar displays because it has advantages of self-luminescence, free-viewing angle, low power consumption, easy fabrication, low cost, low operating temperature range, high response speed and full-colorized display.

The OLED mainly utilizes a self-luminescence feature of the organic electroluminescence device to achieve a display effect. In addition, the organic electroluminescence device is comprised of a pair electrodes and an organic material layer. When a current passes through an anode and a cathode, electrons and holes in the organic material layer combine to form excitons that permit the organic material layer to emit light with different colour in accordance with characteristics of the organic material, thereby allowing the OLED to achieve the display effect.

FIG. 1 schematically shows a conventional organic electroluminescence device structure. As shown in FIG. 1, the conventional organic electroluminescence device 100 comprises a substrate 110, an anode 120, a hole transportation layer 130, a luminescence layer 140, an electron transportation layer 150 and a cathode 160. Electrons are injected into the electron transportation layer 150 from the anode 120, and then transported to the hole transportation layer 130, when a bias voltage is applied to the anode 120 and the cathode 160. On the other hand, the holes are injected into the hole transportation layer 130, and then transported to the luminescence layer 140. In the meantime, the recombination phenomena of the electrons and holes occurs in the luminescence layer 140, which further produces excitons for emitting light.

Among the convention technologies, material of the electron transportation layer 150 is usually Alq3; however, since an electron mobility in Alq3 is smaller than a hole mobility in the hole transportation layer, there exists an carrier transportation non-equilibrium problem in the conventional organic electroluminescence device 100, and this problem in turn affects the organic electroluminescence device 100's light-emitting efficiency.

### SUMMARY OF THE INVENTION

Accordingly, the present invention is directed to provide an organic electroluminescence device that has a higher light-emitting efficiency.

The present invention is further directed to provide a electron transportation layer so as to promote an organic electroluminescence device 100's light-emitting efficiency.

Based on the above and other objectives, an organic electroluminescence device of the present invention comprises a substrate, a first electrode layer, a hole transportation layer, a luminescence layer, an electron transportation layer and a second electrode layer. In addition, on the substrate is disposed the first electrode layer on which the hole transportation layer is disposed. In addition, on the hole transportation is disposed the layer luminescence layer. Moreover, on the luminescence layer is disposed the electron transportation layer on which the second electrode layer is further disposed. Moreover, the electron transportation layer comprises n+1 first sub-transportation layers and n second sub-transportation layers, wherein n is an integer. The n+1 first sub-transportation layers are stacked on the luminescence layer, each of the n second sub-transportation layers is disposed between every two neighbor first sub-transportation layers and a band-gap of the first sub-transportation layer is different from that of second sub-transportation layer.

The organic electroluminescence device further comprises a hole-injected layer that is disposed between the first electrode layer and the hole transportation layer.

The organic electroluminescence device further comprises an electron-injected layer that is disposed between the second electrode layer and the electron transportation layer.

The present invention further provides an electron transportation layer that comprises n+1 first sub-transportation layers and n second sub-transportation layers, wherein n is an integer. The n+1 first sub-transportation layers are stacked one another, and each of the n second sub-transportation layers is disposed between every two neighbor first sub-transportation layers and a band-gap of the first sub-transportation layer is different from that of second sub-transportation layer.

In the organic electroluminescence device and the electron transportation layer, a band-gap of the first sub-transportation layer is larger than that of the second sub-transportation layer.

In the organic electroluminescence device and the electron transportation layer, a band-gap of the first sub-transportation layer is smaller than that of the second sub-transportation layer.

In the organic electroluminescence device and the electron transportation layer, each of the first sub-transportation layers and each of the second sub-transportation layers have thicknesses, for example, between 10˜200 Angstrom.

In the organic electroluminescence device and the electron transportation layer, each of the first sub-transportation layers and each of the second sub-transportation layers have thicknesses, for example, between 20˜100 Angstrom.

In the organic electroluminescence device and the electron transportation layer, each of the first sub-transportation layers and each of the second sub-transportation layers have thicknesses, for example, between 10˜20 Angstrom.

In the organic electroluminescence device and the electron transportation layer, material of the first sub-transportation layers and the second sub-transportation layers, for example, is selected from one of the four compound, each of which has its chemical formulation:
Chemical Formulation (1): 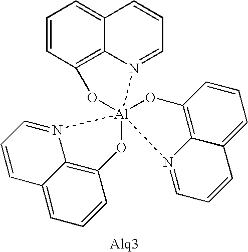
Chemical Formulation (2): 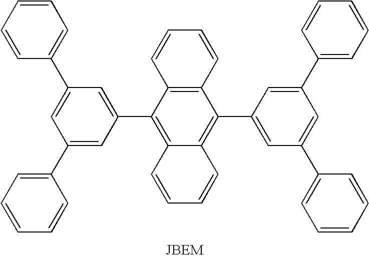
Chemical Formulation (3): 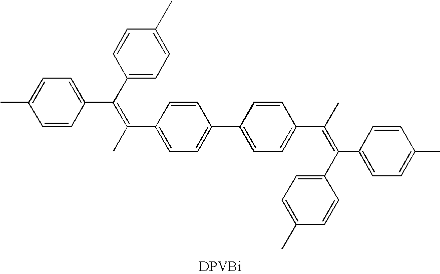
Chemical Formulation (4):

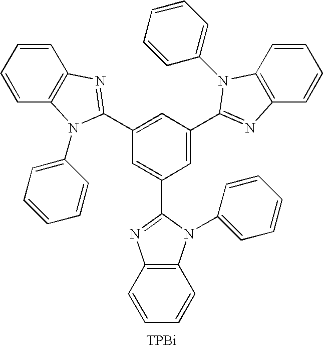

Based on the above description, as the electron transportation layer of the present invention is constituted by a stacked super-lattice structure of the first sub-transportation layers and the second sub-transportation layers, the electron mobility of the electron transportation layer can be promoted and thus ameliorates the carrier transportation non-equilibrium problem occurred in the conventional organic electroluminescence device.

The objectives, other features and advantages of the invention will become more apparent and easily understood from the following detailed description of the invention when taken in conjunction with the accompanying drawings.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 schematically shows a conventional organic electroluminescence device structure.

FIG. 2 schematically shows an organic electroluminescence device structure of one embodiment of the present invention.

FIG. 3 schematically shows an organic electroluminescence device structure of another embodiment of the present invention.

### DESCRIPTION OF THE EMBODIMENTS

Reference will now be made in detail to the present preferred embodiments of the invention, examples of which are illustrated in the accompanying drawings.

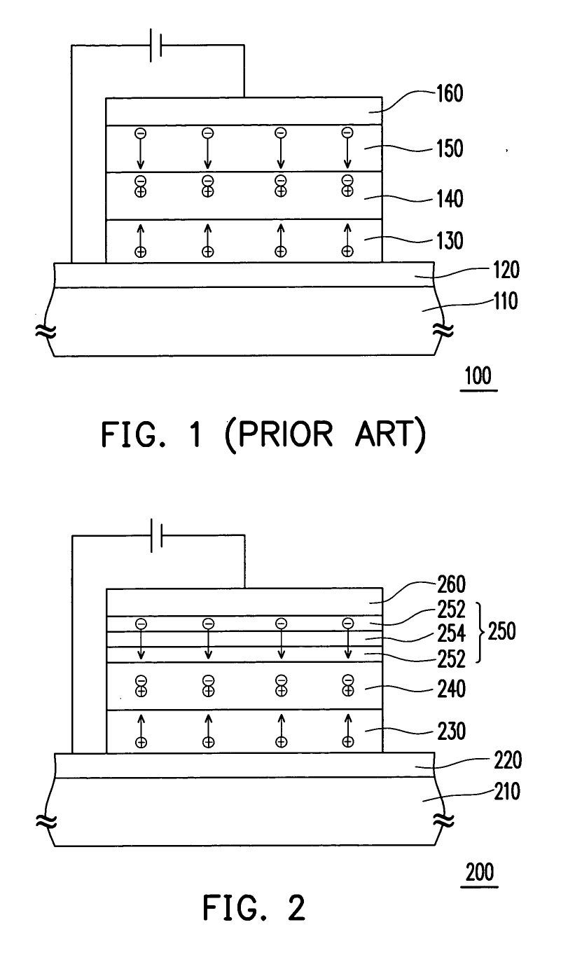

FIG. 2 schematically shows an organic electroluminescence device structure of one embodiment of the present invention. Referring to FIG. 2, an organic electroluminescence device 200 of this embodiment comprises a substrate 210, a first electrode layer 220, a hole transportation layer 230, a luminescence layer 240, an electron transportation layer 250 and a second electrode layer 260. In addition, on the substrate 210 is disposed the first electrode layer 220 on which the hole transportation layer 230 is disposed. Moreover, on the hole transportation layer 230 is disposed the luminescence layer 240 on which the electron transportation layer 250 is further disposed, and eventually, the second electrode layer 260 is disposed on the electron transportation layer 250. Moreover, the electron transportation layer 250 comprises n+1 first sub-transportation layers 252 and n second sub-transportation layers 254, wherein n is an integer. The n+1 first sub-transportation layers 252 are stacked on the luminescence layer 240, each of the n second sub-transportation layers 254 is disposed between every two neighbor first sub-transportation layers 252 and a band-gap of the first sub-transportation layer 252 is different from that of second sub-transportation layer 254.

In the organic electroluminescence device 200, the first electrode layer 220 may be, for example, an anode, and the second electrode layer 260 may be, for example, a cathode. The electrons are injected into the electron transportation layer 250 from the second electrode layer 260, and then transported to the luminescence layer 240, when a bias voltage is applied to the first electrode layer 220 and the second electrode layer 260. On the other hand, the holes are injected into the hole transportation layer 230, and then transported to the luminescence layer 240. In the meantime, the recombination phenomena of the electrons and holes occurs in the luminescence layer 240, which further produces excitons for emitting light.

In this embodiment, the electron transportation layer 250 has a super-lattice structure that is constituted by the first sub-transportation layer 252 and the second sub-transportation layer 254, each of which has a highest occupied molecular orbital and the lowest unoccupied molecular orbital. In addition, a junction between the first sub-transportation layer 252 and the second sub-transportation layer 254, forms a two-dimension quantum well, in which free electrons are generated and wanders around the junction. This electrons generated in the super-lattice structure, is called “two-dimension free electrons.” As the two-dimension free electrons seldom collide one another, their electron mobility is larger than a general electron's electron mobility.

As a result, the electron transportation layer 250 with the super-lattice structure is able to promote electron's mobility so that the electron mobility of the electron transportation layer 250 approaches, even equals, the hole mobility of the hole transportation layer 230, thereby ameliorating the carrier transportation non-equilibrium problem and further promoting the organic electroluminescence device 200's light-emitting efficiency. In addition, since the super-lattice structure has a feature of low resistance, a better ohmic contact between the second electrode layer 260 and the electron transportation layer 250, can be formed so as to promote the organic electroluminescence device 200's light-emitting efficiency and lower its operating voltage.

In one embodiment of the present invention, material of the first sub-transportation layer 252 and the second sub-transportation layer 254 are organic material, which, for example, is selected from one of the four compound, each of which has its chemical formulation:
Chemical Formulation (1): 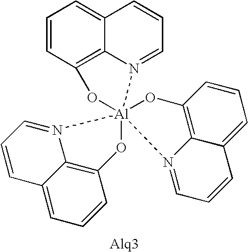
Chemical Formulation (2) 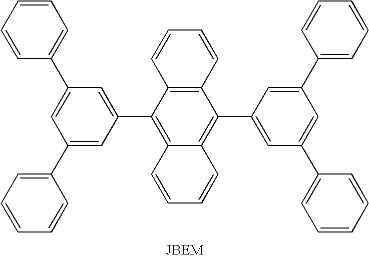
Chemical Formulation (3): 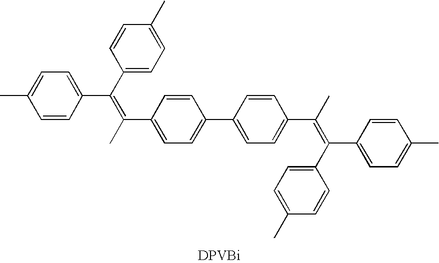
Chemical Formulation (4):

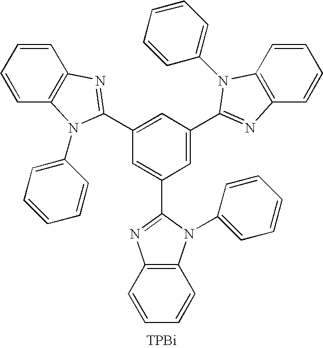

For example, material of the first sub-transportation layer 252 and the second sub-transportation layer 254 are Alq3 with a smaller band-gap and JBEM with a larger band-gap, respectively, or are JBEM and Alq3, respectively. In other words, in this embodiment, the band-gap of the first sub-transportation layer 252 may be larger than that of the second sub-transportation layer 254, or may be smaller than that of the second sub-transportation layer 254.

In this embodiment, the first sub-transportation layer 252 may have, or have not the same thickness as the second sub-transportation layer 254, depending on users' need. In addition, each of the first sub-transportation layers 252 may have, or have not the same thickness as each of the second sub-transportation layers 254, depending on the users' need. Moreover, the first sub-transportation layers and the second sub-transportation layers have thicknesses about between 10-100 Angstrom or between 20-100 Angstrom, and preferably between 10˜20 Angstrom.

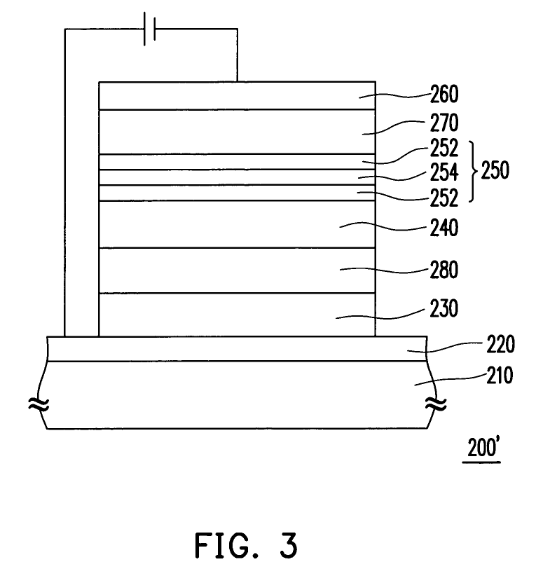

FIG. 3 schematically shows an organic electroluminescence device structure of another embodiment of the present invention. Referring to FIG. 3, it is similar to FIG. 2 except that the organic electroluminescence device 200′ shown in FIG. 3, further comprises an electron-injected layer 270 and a hole-injected layer 280. Moreover, the electron-injected layer 270 is disposed between the second electrode layer 260 and the eelectron transportation layer 250, while the hole-injected layer 280 is disposed between the hole transportation layer 230 and the first electrode layer 220, thereby promoting the light-emitting efficiency of the organic electroluminescence device 200′.

It is noticeable that one of the electron-injected layer 270 and the hole-injected layer 280, can be chosen to be disposed inside the organic electroluminescence device 200′. In addition, although the aforementioned embodiment employs the electron transportation layer 250 comprised of the first sub-transportation layer 252 and the second sub-transportation layer 254, the present invention is not limited to this embodiment. Actually, the embodiment may increase the number of the first sub-transportation layers 252 and the second sub-transportation layers 254.

In conclusion, the organic electroluminescence device of the present invention at least has the following advantages:
1. As the electron transportation layer of the present invention has a higher electron's mobility because of the electron transportation layer being comprised of the first sub-transportation layer and the second sub-transportation layer with their thickness less than 10-200 Angstrom, and an overlapped energy gap between these two sub-transportation layers, the carrier transportation non-equilibrium occurred in the conventional technology, can be ameliorated, which further promotes the organic electroluminescence device's light-emitting efficiency.
2. As the electron transportation layer of the present invention has a feature of low resistance, a better ohmic contact between the second electrode layer and the electron transportation layer, can be formed, thereby promoting the organic electroluminescence device's light-emitting efficiency and lowering its operating voltage.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. An organic electroluminescence device, comprising:
a substrate,
a first electrode layer,
a hole transportation layer,
a luminescence layer,
an electron transportation layer, comprising:
n+1 first sub-transportation layers, stacked on the luminescence layer, wherein n is an integer; and
n second sub-transportation layers, each of which is disposed between every two neighbor first sub-transportation layers and a band-gap of the first sub-transportation layer is different from that of second sub-transportation layer; and
a second electrode layer, disposed on the electron transportation layer.

2. The organic electroluminescence device according to claim 1, wherein the band-gap of the first sub-transportation layer is larger than that of second sub-transportation layer.

3. The organic electroluminescence device according to claim 1, wherein the band-gap of the first sub-transportation layer is smaller than that of second sub-transportation layer.

4. The organic electroluminescence device according to claim 1, wherein the each of the first sub-transportation layers and each of the second sub-transportation layers have thicknesses, for example, between 10˜200 Angstrom.

5. The organic electroluminescence device according to claim 1, wherein the each of the first sub-transportation layers and each of the second sub-transportation layers have thicknesses, for example, between 20˜100 Angstrom.

6. The organic electroluminescence device according to claim 1, wherein the each of the first sub-transportation layers and each of the second sub-transportation layers have thicknesses, for example, between 10˜20 Angstrom.

7. The organic electroluminescence device according to claim 1, wherein the material of the first sub-transportation layers and the second sub-transportation layers, for example, is selected from one of the four compound, each of which has its chemical formulation:
Chemical Formulation (1): 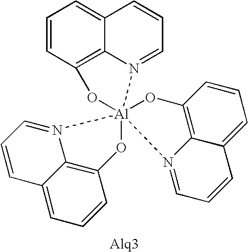
Chemical Formulation (2): 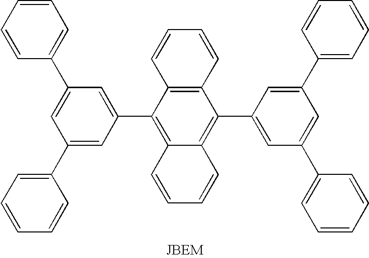
Chemical Formulation (3): 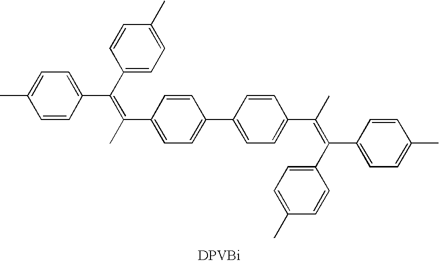
Chemical Formulation (4):

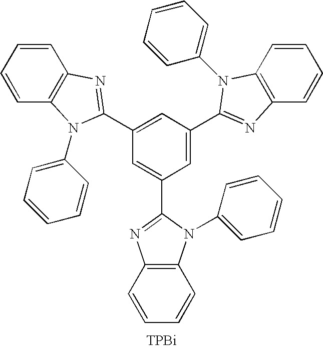

8. The organic electroluminescence device according to claim 1, further comprises a hole-injected layer disposed between the first electrode layer and the hole transportation layer.

9. The organic electroluminescence device according to claim 1, further comprises an electron-injected layer disposed between the second electrode layer and the electron transportation layer.

10. An electron transportation layer, suitable for an organic electroluminescence device, the electron transportation layer comprising:
n+1 first sub-transportation layers, each of which is stacked one another, and n is an integer; and
n second sub-transportation layers, each of which is disposed between every two neighbor first sub-transportation layers and a band-gap of the first sub-transportation layer is different from that of second sub-transportation layer.

11. The organic electroluminescence device according to claim 9, wherein the band-gap of the first sub-transportation layer is larger than that of second sub-transportation layer.

12. The organic electroluminescence device according to claim 9, wherein the band-gap of the first sub-transportation layer is smaller than that of second sub-transportation layer.

13. The organic electroluminescence device according to claim 9, wherein the each of the first sub-transportation layers and each of the second sub-transportation layers have thicknesses, for example, between 10˜200 Angstrom.

14. The organic electroluminescence device according to claim 9, wherein the each of the first sub-transportation layers and each of the second sub-transportation layers have thicknesses, for example, between 20˜100 Angstrom.

15. The organic electroluminescence device according to claim 10, wherein the each of the first sub-transportation layers and each of the second sub-transportation layers have thicknesses, for example, between 10˜20 Angstrom.

16. The organic electroluminescence device according to claim 9, wherein the material of the first sub-transportation layers and the second sub-transportation layers, for example, is selected from one of the four compound, each of which has its chemical formulation:
Chemical Formulation (1): 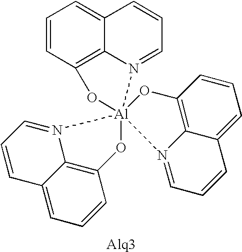
Chemical Formulation (2): 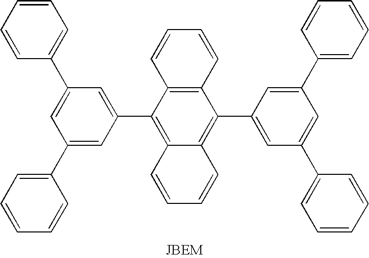
Chemical Formulation (3): 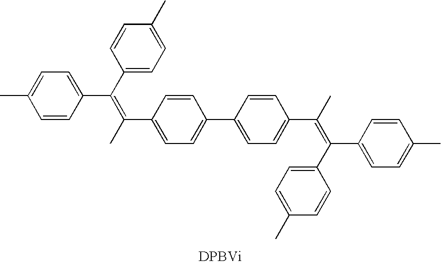
Chemical Formulation (4): [chemical structure]
